(19) United States
(12) Patent Application Publication
(10) Pub. No.: US 2026/0060009 A1
(43) Pub. Date: Feb. 26, 2026

(54) SEMICONDUCTOR DEVICE AND MANUFACTURING METHOD OF SEMICONDUCTOR DEVICE

(71) Applicant: SK hynix Inc., Icheon-si (KR)

(72) Inventor: Hong Ju SUH, Icheon-si (KR)

(73) Assignee: SK hynix Inc., Icheon-si (KR)

(21) Appl. No.: 18/944,974

(22) Filed: Nov. 12, 2024

(30) Foreign Application Priority Data
Aug. 22, 2024 (KR) 10-2024-0112614

(51) Int. Cl. H10N 70/00; H10B 63/00; H10N 70/20

(52) U.S. Cl. CPC H10N 70/8418; H10B 63/80; H10N 70/011; H10N 70/24; H10N 70/826

(57) ABSTRACT

A semiconductor device may include: a first electrode; a switching pattern located inside a trench of the first electrode; an oxygen reservoir pattern located on the switching pattern and having a smaller width than the switching pattern; a second electrode located on the oxygen reservoir pattern; and an insulating spacer surrounding a sidewall of the oxygen reservoir pattern.

### CROSS-REFERENCE TO RELATED APPLICATION

This application claims priority under 35 U.S. C. § 119 to Korean Patent Application No. 10-2024-0112614 filed on Aug. 22, 2024 in the Korean Intellectual Property Office, which is incorporated herein by reference in its entirety.

### BACKGROUND

### 1. Technical Field

Embodiments of the present disclosure relate to an electronic device, and more particularly, to a semiconductor device and a manufacturing method of the semiconductor device.

### 2. Related Art

Recently, in accordance with miniaturization, low power consumption, performance improvement, diversification, and the like of electronic devices, semiconductor devices capable of storing information have been demanded in various electronic devices such as computers and portable communication devices. Accordingly, research into semiconductor devices capable of storing data using characteristics of switching between different resistance states depending on an applied voltage or current has been conducted. Examples of such semiconductor devices include a resistive random access memory (RRAM), a phase-change random access memory (PRAM), a ferroelectric random access memory (FRAM), a magnetic random access memory (MRAM), and the like.

### SUMMARY

In an embodiment, a semiconductor device may include: a first electrode with a trench; a switching pattern disposed in the trench of the first electrode; an oxygen reservoir pattern disposed on the switching pattern and having a smaller width in a horizontal direction than the switching pattern; a second electrode disposed on the oxygen reservoir pattern; and an insulating spacer surrounding a sidewall of the oxygen reservoir pattern.

In an embodiment, a semiconductor device may include: a switching pattern; a first electrode surrounding a bottom surface and a sidewall of the switching pattern; an oxygen reservoir pattern located on the switching pattern; a second electrode located on the oxygen reservoir pattern and having a smaller width than the switching pattern; and an insulating spacer located between the first electrode and the second electrode.

In an embodiment, a manufacturing method of a semiconductor device may include: forming a first electrode; forming a switching pattern inside a trench of the first electrode; forming an oxygen reservoir pattern on the switching pattern, the oxygen reservoir pattern having a smaller width than the switching pattern; forming a second electrode on the oxygen reservoir pattern; and forming an insulating spacer on a sidewall of the oxygen reservoir pattern.

### BRIEF DESCRIPTION OF THE DRAWINGS

FIG. 1 is a diagram illustrating the structure of a semiconductor device in accordance with an embodiment of the disclosure.

FIGS. 2A to 2C are diagrams illustrating the structure of a semiconductor device in accordance with an embodiment of the disclosure.

FIGS. 3A to 3C are diagrams illustrating the structure of a semiconductor device in accordance with an embodiment of the disclosure.

FIGS. 4A and 4B are diagrams for describing an operation of a semiconductor device in accordance with an embodiment of the disclosure.

FIGS. 5A to 5G are diagrams describing a manufacturing method of a semiconductor device in accordance with an embodiment of the disclosure.

FIGS. 6A to 6G are diagrams for describing a manufacturing method of a semiconductor device in accordance with an embodiment of the disclosure.

### DETAILED DESCRIPTION

Various embodiments are directed to a semiconductor device having a stable structure and improved characteristics and a manufacturing method of the semiconductor device.

It is possible to improve the degree of integration, operating characteristics, and reliability of a semiconductor device.

Hereafter, embodiments in accordance with the technical spirit of the present disclosure will be described with reference to the accompanying drawings.

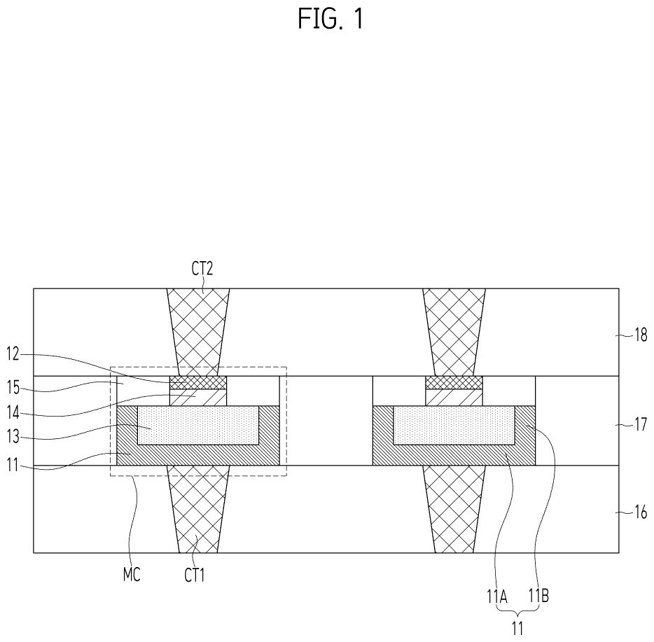

FIG. 1 is a diagram illustrating the structure of a semiconductor device in accordance with an embodiment of the disclosure.

Referring to FIG. 1, a semiconductor device may include a memory cell MC, and may further include a first contact plug CT1, a second contact plug CT2, a first interlayer insulating layer 16, a second interlayer insulating layer 17, and a third interlayer insulating layer 18. The first contact plug CT1 may be located in the first interlayer insulating layer 16, and the second contact plug CT2 may be located in the third interlayer insulating layer 18.

The memory cell MC may be located in the second interlayer insulating layer 17, and may be a resistive memory cell. The memory cell MC may include a first electrode 11, a second electrode 12, a switching pattern 13, and an oxygen reservoir pattern 14, and may further include an insulating spacer 15. The first electrode 11 may be electrically connected to the first contact plug CT1, and the second electrode 12 may be electrically connected to the second contact plug CT2.

The first electrode 11 may have a U shape cross-section. As an example, the first electrode 11 may include a plate portion 11A and sidewall portions 11B. The plate portion 11A may extend in a horizontal direction. The sidewall portion 11B may protrude from the plate portion 11A, and may extend in a vertical direction.

The first electrode 11 may include a conductive material such as polysilicon or metal. As an example, the first electrode 11 may include polysilicon, tungsten (W), tungsten nitride (WNₓ), tungsten silicide (WSiₓ), titanium (Ti), titanium nitride (TiNₓ), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SiC), silicon carbonitride (SiCN), copper (Cu), zinc (Zn), nickel (Ni), cobalt (Co), lead (Pb), platinum (Pt), molybdenum (Mo), ruthenium (Ru), palladium (Pd), iridium (Ir), hafnium (Hf), niobium (Nb), vanadium (V), niobium nitride (NbN), or the like, or include combinations thereof.

The switching pattern 13 may be located inside the first electrode 11. The first electrode 11 may surround a bottom surface and sidewalls of the switching pattern 13. The switching pattern 13 may be disposed on the plate portion 11A of the first electrode, and the sidewall portions 11B may surround the sidewalls of the switching pattern 13. An upper surface of the switching pattern 13 may be located on substantially the same plane as an upper surface of the sidewall portions 11B of the first electrode 11.

The switching pattern 13 may have variable resistance characteristics, in which the pattern exhibits different resistance states depending on a voltage or a current supplied through the first electrode 11 and/or the second electrode 12. As an example, resistance of the switching pattern 13 may change as a result of the generation, partial generation, or electrical disconnection of a filament within the pattern. The filament may be a conductive filament, and may electrically connect the first electrode 11 and the second electrode 12 to each other. The filament may be generated, partially generated, or dissipated depending on the movement of oxygen vacancies. Here, an oxygen vacancy may be a lattice defect occurring when oxygen departs from a location in which the oxygen was held by a bond. The oxygen vacancy may exhibit the same behavior as a particle having a positive charge, such as a hole. When oxygen vacancies are connected, a filament may be generated, and when oxygen vacancies are disconnected from each other, the filament may degrade and dissipate.

The switching pattern 13 may include metal oxide, and the metal included in the switching pattern 13 may be transition metal. As an example, the switching pattern 13 may include metal such as Al, Si, Ti, Cr, Mn, Ni, Cu, Zn, Y, Zr, Nb, Hf, Ta, or W. The switching pattern 13 may include Al₂O₃, ZnO, Ta₂Oₓ, HfOₓ, TiOₓ, ZrOₓ, or the like.

The oxygen reservoir pattern 14 may be located on the switching pattern 13. The oxygen reservoir pattern 14 may have a smaller width in a horizontal direction than the switching pattern 13. The oxygen reservoir pattern 14 may be located outside the first electrode 11. The upper surface of the switching pattern 13 and the uppermost surfaces of the first electrode 11 may be located on substantially the same plane.

The oxygen reservoir pattern 14 may reserve the oxygen vacancies necessary for the generation of the filament. During resistance switching driving of the memory cell MC, oxygen ions and/or the oxygen vacancies may be exchanged between the switching pattern 13 and the oxygen reservoir pattern 14. As an example, during a set operation, a filament may be generated in the switching pattern 13 with oxygen vacancies supplied from the oxygen reservoir pattern 14, and resistance of the switching pattern 13 may decrease. During a reset operation, the oxygen vacancies of the filament may be transferred to the oxygen reservoir pattern 14, such that the filament may dissipate and the resistance of the switching pattern 13 may increase. The oxygen reservoir pattern 14 may include metal or metal oxide. As an example, the oxygen reservoir pattern 14 may include metal such as Ta, Ti, Hf, Nb, or TaN.

The second electrode 12 may be located on the oxygen reservoir pattern 14. The second electrode 12 may have a smaller width than the switching pattern 13. Sidewalls of the second electrode 12 and sidewalls of the oxygen reservoir pattern 14 may be aligned with each other. The second electrode 12 and the oxygen reservoir pattern 14 may have substantially the same width.

The second electrode 12 may include a conductive material such as polysilicon or metal. As an example, the second electrode 12 may include polysilicon, tungsten (W), tungsten nitride (WNₓ), tungsten silicide (WSiₓ), titanium (Ti), titanium nitride (TiNₓ), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SiC), silicon carbonitride (SiCN), copper (Cu), zinc (Zn), nickel (Ni), cobalt (Co), lead (Pb), platinum (Pt), molybdenum (Mo), ruthenium (Ru), palladium (Pd), iridium (Ir), hafnium (Hf), niobium (Nb), vanadium (V), niobium nitride (NbN), or the like, or include combinations thereof.

The insulating spacer 15 may surround the sidewalls of the oxygen reservoir pattern 14, and may extend to the sidewalls of the second electrode 12 and the upper surface of the first electrode 11. The insulating spacer 15 may be located between the first electrode 11 and the second electrode 12, and may insulate the first electrode 11 and the second electrode 12 from each other. An upper surface of the insulating spacer 15 and an upper surface of the second electrode 12 may be located on substantially the same plane. As an example, the insulating spacer 15 may include an insulating material such as oxide or nitride.

According to the structure described above, an electric field may be formed on a side surface of the switching pattern 13, and data retention characteristics may be improved through a horizontal electric field. Here, the horizontal electric field may be an electric field in the horizontal direction, and may be a lateral electric field. In addition, by controlling lateral diffusion of the oxygen vacancies through the horizontal electric field, it is possible to improve a negative set phenomenon.

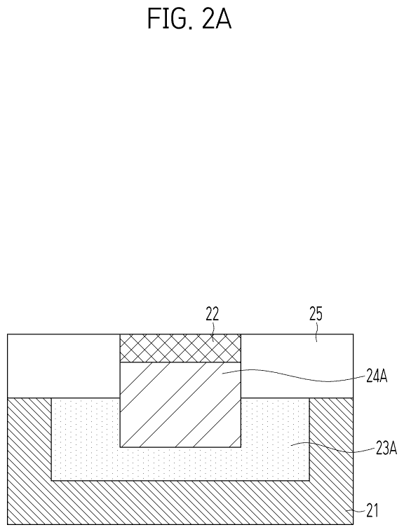

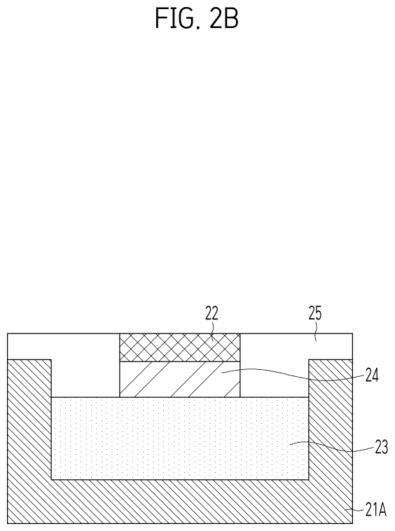

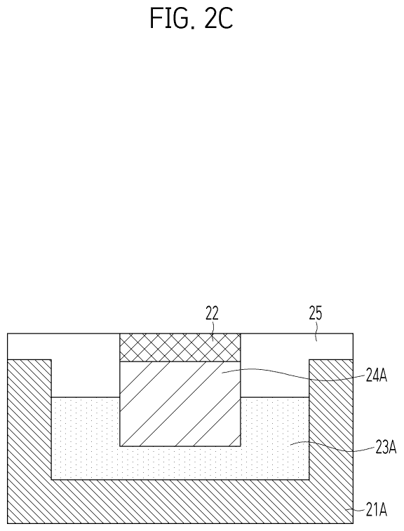

FIGS. 2A to 2C are diagrams illustrating the structure of a semiconductor device in accordance with an embodiment of the disclosure. Hereinafter, content overlapping with the previously described content may be omitted.

Referring to FIG. 2A, a semiconductor device may include a first electrode 21, a second electrode 22, a switching pattern 23A, an oxygen reservoir pattern 24A, and an insulating spacer 25. The first electrode 21 may have a U-shaped cross-section, and the switching pattern 23A may be located inside the U-shaped cross-section of the first electrode 21.

The oxygen reservoir pattern 24A may be located on the switching pattern 23A, and may protrude into the switching pattern 23A. The switching pattern 23A may surround a bottom surface of the oxygen reservoir pattern 24A, and may extend along sidewalls of the oxygen reservoir pattern 24A. The switching pattern 23A may surround portions of the sidewalls of the oxygen reservoir pattern 24A. The switching pattern 23A may have a U-shaped cross-section.

A portion of the oxygen reservoir pattern 24A and the switching pattern 23A may be located inside the U-shaped cross-section of the of the first electrode 21. An upper surface of the switching pattern 23A may be located on substantially the same plane as an upper surface of the first electrode 21.

The second electrode 22 may be located on the oxygen reservoir pattern 24A. The insulating spacer 25 may be located on the switching pattern 23A, and may surround the sidewalls of the oxygen reservoir pattern 24A and sidewalls of the second electrode 22. Lower sidewalls of the oxygen reservoir pattern 24A may be surrounded by the switching pattern 23A, and upper sidewalls of the oxygen reservoir pattern 24A may be surrounded by the insulating spacer 25. The insulating spacer 25 may extend to the upper surface of the first electrode 21. An upper surface of the second electrode 22 and an upper surface of the insulating spacer 25 may be located on substantially the same plane.

Referring to FIG. 2B, a semiconductor device may include a first electrode 21A, a second electrode 22, a switching pattern 23, an oxygen reservoir pattern 24, and an insulating spacer 25. The first electrode 21A may have a U-shaped cross-section, and may surround a bottom surface and sidewalls of the switching pattern 23. The switching pattern 23 and the oxygen reservoir pattern 24 may be located inside the U-shaped cross-section of the first electrode 21A, and an upper surface of the oxygen reservoir pattern 24 may be located on substantially the same plane as an upper surface of the first electrode 21A.

The oxygen reservoir pattern 24 may be located on the switching pattern 23, and may be located inside the first electrode 21A. A lower surface of the second electrode 22 and the upper surface of the first electrode 21A may be located on substantially the same plane.

The second electrode 22 may be located on the oxygen reservoir pattern 24. A lower surface of the second electrode 22 may be located on substantially the same plane as an upper surface of the first electrode 21. The insulating spacer 25 may surround sidewalls of the oxygen reservoir pattern 24 and sidewalls of the second electrode 22, and may extend to cover an upper surface of the first electrode 21A.

Referring to FIG. 2C, a semiconductor device may include a first electrode 21A, a second electrode 22, a switching pattern 23A, an oxygen reservoir pattern 24A, and an insulating spacer 25. The switching pattern 23A may have a U-shaped cross-section. The oxygen reservoir pattern 24A may protrude into the switching pattern 23A, and the switching pattern 23A may surround a bottom surface and lower sidewalls of the oxygen reservoir pattern 24A. The insulating spacer 25 may surround upper sidewalls of the oxygen reservoir pattern 24A and sidewalls of the second electrode 22, and may extend to cover an upper surface of the first electrode 21A.

According to the structure described above, a horizontal electric field may be formed by the first electrode 21A, which has a cross-sectional U shape. Accordingly, data retention characteristics and a negative set phenomenon may be improved.

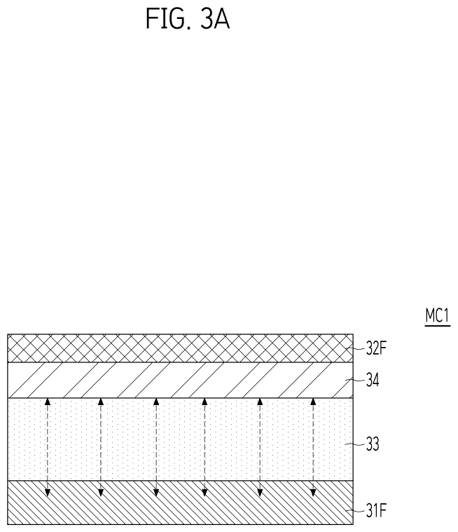

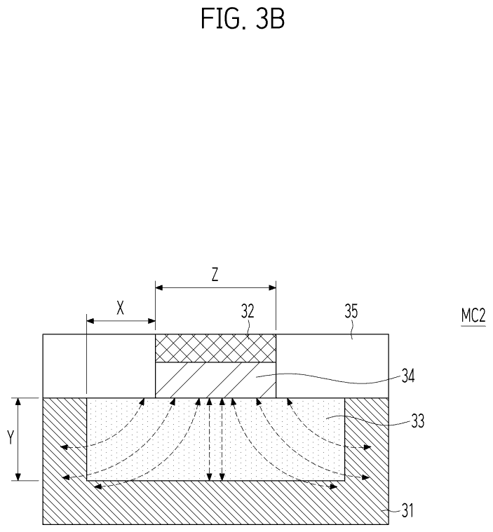

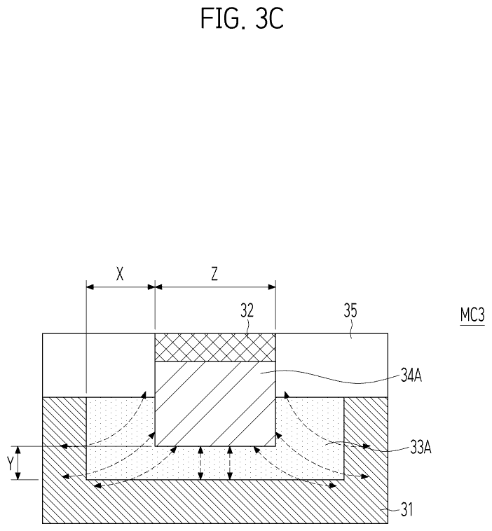

FIGS. 3A to 3C are diagrams illustrating the structure of a semiconductor device in accordance with an embodiment of the disclosure. Hereinafter, content overlapping with the previously described content may be omitted.

Referring to FIG. 3A, a first memory cell MC1 may include a first electrode 31F, a second electrode 32F, a switching pattern 33, and an oxygen reservoir pattern 34. Here, the first electrode 31F and the second electrode 32F may each have a flat plate shape. In such a case, an electric field may be formed in a vertical direction.

Referring to FIG. 3B, a second memory cell MC2 may include a first electrode 31, a second electrode 32, a switching pattern 33, an oxygen reservoir pattern 34, and an insulating spacer 35. Because the first electrode 31 surrounds sidewalls of the switching pattern 33, an electric field may be formed in a lateral direction as well as in the vertical direction.

Referring to FIG. 3C, a third memory cell MC3 may include a first electrode 31, a second electrode 32, a switching pattern 33A, an oxygen reservoir pattern 34A, and an insulating spacer 35. The oxygen reservoir pattern 34A may protrude into the switching pattern 33A. The switching pattern 33A may surround a bottom surface and sidewalls of the oxygen reservoir pattern 34A. Accordingly, compared to memory cells in which the switching pattern 33A does not surround the sidewalls of the oxygen reservoir pattern 34A, in memory cell MC3, an electric field is concentrated on side surfaces of the switching pattern 33A, thereby increasing the magnitude of a horizontal electric field.

The first memory cell MC1 may operate using only a vertical electric field, while the second and third memory cells MC2 and MC3 may operate using both a vertical electric field and a horizontal electric field. A magnitude of the horizontal electric field may be adjusted by changing the materials in the layers, the distance between the layers, and the like. As an example, referring to FIGS. 3B and 3C, when a width Z of the oxygen reservoir pattern 34 or 34A is fixed, a horizontal distance X between the first electrode 31 and the oxygen reservoir pattern 34 or 34A may be reduced or a vertical distance Y between the first electrode 31 and the oxygen reservoir pattern 34 or 34A may be reduced. By changing the dimensions of memory cell elements, it is possible to increase the horizontal electric field applied to the oxygen reservoir pattern 34 or 34A. When the width Z of the oxygen reservoir pattern 34 or 34A and the vertical distance Y are fixed, the horizontal distance X may be reduced. Through this, it is possible to increase the horizontal electric field on the side surfaces of the oxygen reservoir pattern 34 or 34A. In the second memory cell MC2 and the third memory cell MC3, the widths Z of the oxygen reservoir patterns 34 and 34A are the same as each other, but the vertical distance Y of the third memory cell MC3 is smaller than the vertical distance Y of the second memory cell MC2, and thus, the horizontal electric field of the third memory cell MC3 may be stronger than that of the second memory cell MC2.

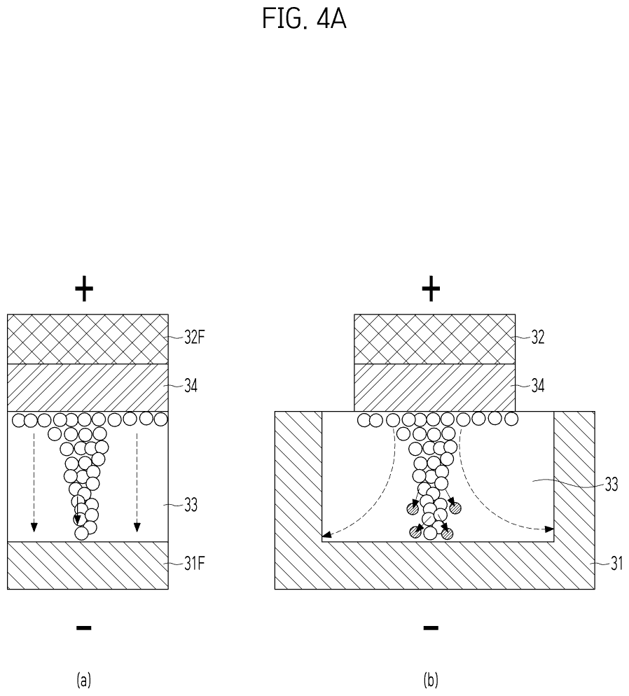

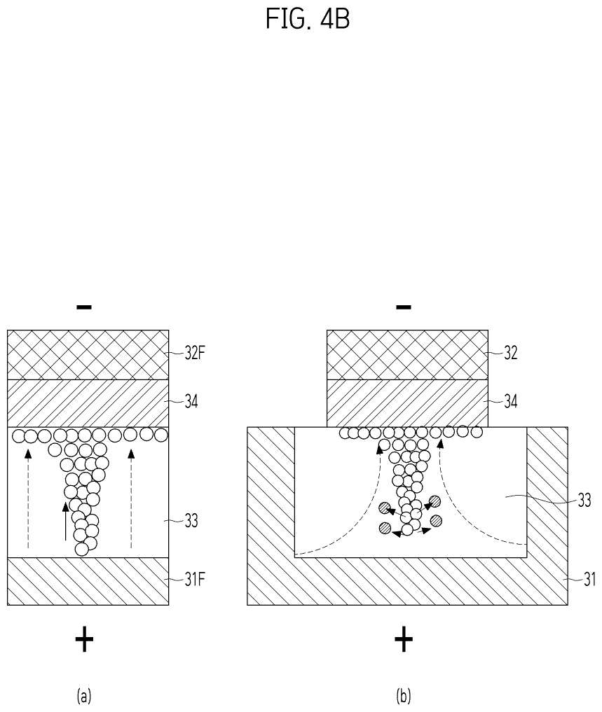

FIGS. 4A and 4B are diagrams for describing an operation of a semiconductor device in accordance with an embodiment of the disclosure. FIG. 4A illustrates the generation of a filament in a set operation, and FIG. 4B illustrates the dissipation of the filament in a reset operation. Hereinafter, content overlapping with the previously described content may be omitted.

Referring to FIG. 4A, the set operation may be performed by applying a set voltage having a first polarity to a memory cell. As an example, the set operation may be performed by applying a negative voltage to first electrode 31F or 31 and applying a positive voltage to second electrode 32F or 32. In the set operation, oxygen vacancies move from oxygen reservoir pattern 34 toward the first electrode 31F or 31, and a filament is formed in switching pattern 33. The shapes of the filaments in examples (a) and (b) may be different depending on the vertical electric field and the horizontal electric field.

Referring to (a) of FIG. 4A, the filament is formed only by the vertical electric field, and may thus have a conical shape. The conical-shaped filament may have a relatively greater area common to a surface of the second electrode 32F, and may have a relatively smaller area common to a surface of the first electrode 31F. When a switching operation of the memory cell illustrated in (a) is repeated, oxygen vacancies may laterally diffuse as they move toward the first electrode 31F. The filament may be disconnected due to the movement of the oxygen vacancies in the horizontal direction, and data retention characteristics may deteriorate.

Referring to (b) of FIG. 4A, a filament is formed under the influence of both a vertical electric field and a horizontal electric field. Because oxygen vacancies move toward side surfaces of the first electrode 31 due to the horizontal electric field, an area of the filament may increase in the vicinity of the first electrode 31. Accordingly, even though oxygen vacancies laterally diffuse in the vicinity of the first electrode 31 as the switching operation of the memory cell is repeated, the filament does not disconnect, and the data retention characteristics may be improved.

Referring to FIG. 4B, a reset operation may be performed by applying a reset voltage having a second polarity different from the first polarity to the memory cell. As an example, the reset operation may be performed by applying a positive voltage to the first electrode 31F or 31 and applying a negative voltage to the second electrode 32F or 32. In the reset operation, oxygen vacancies move to the oxygen reservoir pattern 34, and oxygen vacancies are disconnected from each other, such that the filament dissipates. Referring to (a) of FIG. 4B, a negative set phenomenon in which oxygen vacancies are supplied from the first electrode 31F by the vertical electric field may occur. According to the negative set phenomenon, the filament does not disappear because of the oxygen vacancies supplied from the first electrode 31F, and the memory cell has a set state rather than a reset state. Referring to (b) of FIG. 4B, oxygen vacancies may separate from the filament under the horizontal electric field, and the negative set phenomenon may be avoided or mitigated.

By using the horizontal electric field for the set operation and/or the reset operation as described above, it is possible to improve the control of the generation and the dissipation of the filament and to improve data retention characteristics. The resistance of the memory cell may change in proportion to the applied voltage, and the memory cell has improved analog characteristics. Accordingly, a memory cell operating using a horizontal electric field may be used in analog computing in memory (ACIM), and multiply-accumulated operation (MAC) linearity and accuracy may be improved.

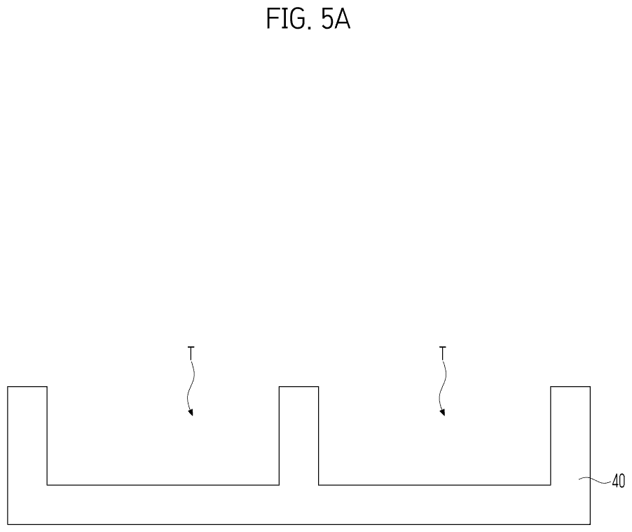

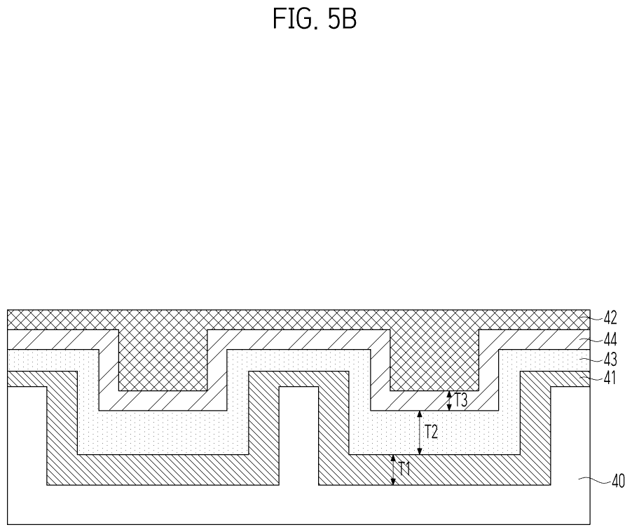

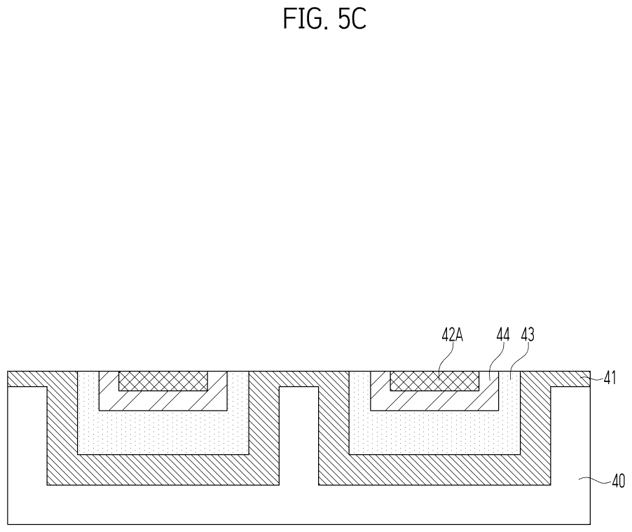

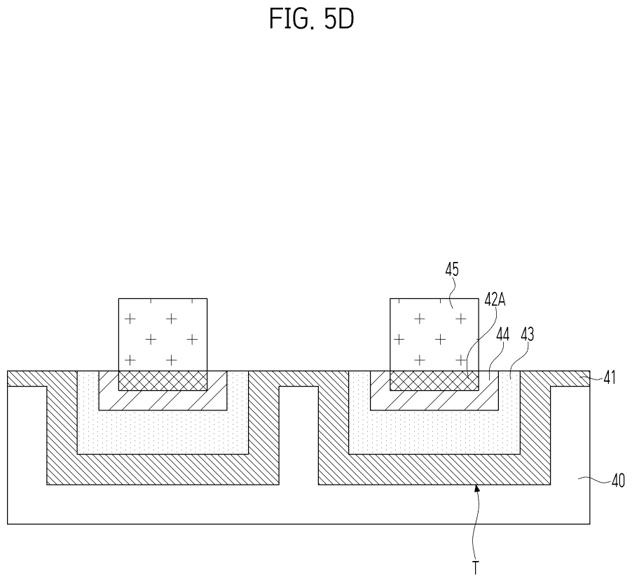

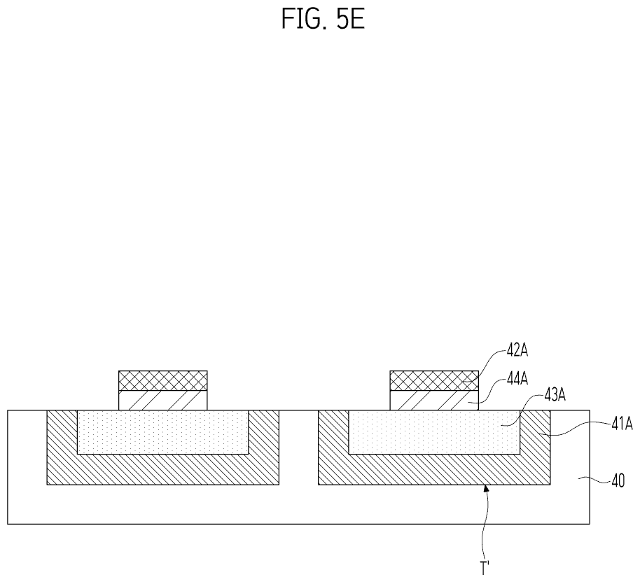

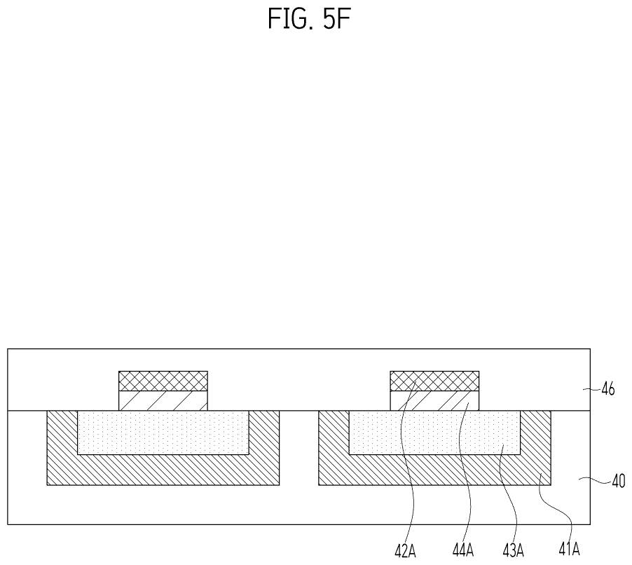

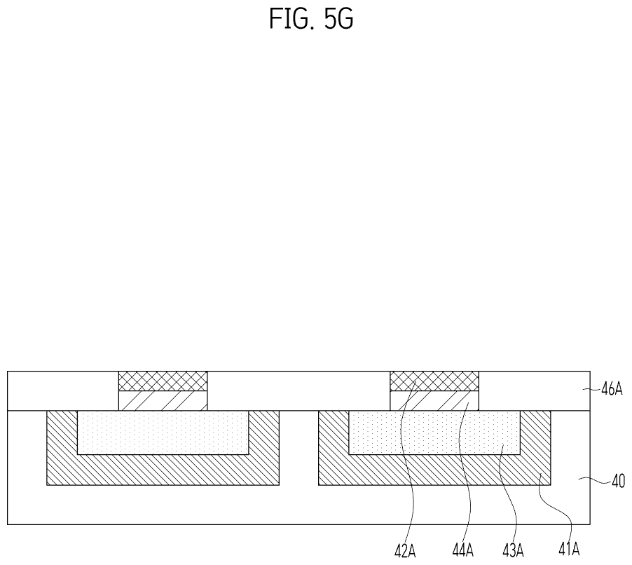

FIGS. 5A to 5G are diagrams describing a manufacturing method of a semiconductor device in accordance with an embodiment of the disclosure. Hereinafter, content overlapping with the previously described content may be omitted.

Referring to FIGS. 5A to 5G, a first electrode 41A may be formed, a switching pattern 43A may be formed on the first electrode 41A, an oxygen reservoir pattern 44A having a smaller width than the switching pattern 43A may be formed on the switching pattern 43A, a second electrode 42A may be formed on the oxygen reservoir pattern 44A, and an insulating spacer 46A may be formed on sidewalls of the oxygen reservoir pattern 44A. The order of forming the first electrode 41A, the switching pattern 43A, the oxygen reservoir pattern 44A, the second electrode 42A, and the insulating spacer 46A may be changed depending on a manufacturing method.

Referring to FIG. 5A, trenches T may be formed in an insulating layer 40. As an example, a mask pattern may be formed on the insulating layer 40, and the trenches T may be formed by etching the insulating layer 40 using the mask pattern as an etching barrier. Here, the mask pattern may be a photoresist pattern.

The trenches T are used to form memory cells, and a width and a depth of each of the trenches T may be determined in consideration of the size of each memory cell to be formed. The trenches T may each have a circular shape, an elliptical shape, a polygonal shape, or the like, in a plan view. The trenches T may be formed at a depth at which they do not penetrate through the insulating layer 40.

Referring to FIG. 5B, a first electrode layer 41 may be formed. The first electrode layer 41 may be formed along a profile of the trenches T. The first electrode layer 41 may be formed not only inside the trenches T, but also on upper surfaces of the insulating layer 40. The first electrode layer 41 may have a first thickness T1 inside the trenches T.

Subsequently, a switching layer 43 may be formed on the first electrode layer 41. The switching layer 43 may be formed along a surface of the first electrode layer 41. The switching layer 43 may be formed not only inside the trenches T, but also outside the trenches T. A second thickness T2 of the switching layer 43 may be greater than the first thickness T1 of the first electrode layer 41 inside the trenches T.

Subsequently, an oxygen reservoir layer 44 may be formed on the switching layer 43. The oxygen reservoir layer 44 may be formed along a surface of the switching layer 43. The oxygen reservoir layer 44 may be formed not only inside the trenches T, but also outside the trenches T. A third thickness T3 of the oxygen reservoir layer 44 may be smaller than the second thickness T2 of the switching layer 43 and may be smaller than the first thickness T1 of the first electrode layer 41 inside the trenches T.

Subsequently, a second electrode layer 42 may be formed on the oxygen reservoir layer 44. The second electrode layer 42 may be formed to fill remaining inner portions of the trenches T. The second electrode layer 42 may also be formed outside the trenches T.

Referring to FIG. 5C, the second electrode layer 42, the oxygen reservoir layer 44, the switching layer 43, and the first electrode layer 41 may be etched. As an example, the second electrode layer 42, the oxygen reservoir layer 44, the switching layer 43, and the first electrode layer 41 may be etched using an etch-back process or a chemical mechanical polish (CMP) process. Upper surfaces of the etched second electrode layer 42, oxygen reservoir layer 44, switching layer 43, and first electrode layer 41 may be located on substantially the same plane.

A portion of the second electrode layer 42 extending in the horizontal direction over an upper surface of the insulating layer 40 may be etched to form the second electrode 42A. A portion of the oxygen reservoir layer 44 extending in the horizontal direction over an upper surface of the insulating layer 40 may be etched. A portion of the switching layer 43 extending in the horizontal direction over an upper surface of the insulating layer 40 may be etched. The switching layer 43 may have a U shape and may surround a bottom surface and sidewalls of the oxygen reservoir layer 44. The oxygen reservoir layer 44 may have a U shape and may surround a bottom surface and sidewalls of the second electrode 42A.

A portion of the first electrode layer 41 extending in the horizontal direction on the upper surface of the insulating layer 40 may be etched. However, the first electrode layer 41 may be partially etched so that the upper surface of the insulating layer 40 is not exposed, while the first electrode layer 41 may be exposed between the trenches T.

Referring to FIG. 5D, a mask pattern 45 may be formed on the second electrode 42A. The mask pattern 45 may be a photoresist pattern. The mask pattern 45 may be formed to cover at least a portion of the second electrode 42A. As an example, the mask pattern 45 may have substantially the same width as the second electrode 42A, while portions of the oxygen reservoir layer 44, the switching layer 43, and the first electrode layer 41 are exposed.

Referring to FIG. 5E, the oxygen reservoir layer 44, the switching layer 43, and the first electrode layer 41 may be etched using the mask pattern 45 as an etching barrier. As an example, the oxygen reservoir layer 44, the switching layer 43, and the first electrode layer 41 may be etched using an etch-back process. The oxygen reservoir pattern 44A may be formed by etching the oxygen reservoir layer 44. The switching pattern 43A may be formed by etching the switching layer 43. The first electrode 41A may be formed by etching the first electrode layer 41. After etching, upper surfaces of the switching pattern 43A and the first electrode 41A may be located on substantially the same plane.

In a process of etching the oxygen reservoir layer 44, the switching layer 43, and the first electrode layer 41, the insulating layer 40 may be partially etched, and the depth of the trenches T in the insulating layer 40 may be reduced to result in trenches T′. Upper surfaces of the insulating layer 40 may be exposed between the trenches T′. The first electrode 41A and the switching pattern 43A may be located inside the trenches T′, and the oxygen reservoir pattern 44A and the second electrode 42A may be located outside the trenches T′.

The oxygen reservoir pattern 44A may have substantially the same width as the second electrode 42A, and sidewalls of the oxygen reservoir pattern 44A and sidewalls of the second electrode 42A may be aligned with each other. The switching pattern 43A may have a greater width than the oxygen reservoir pattern 44A. The first electrode 41A may surround a bottom surface and sidewalls of the switching pattern 43A. The switching pattern 43A may be located inside the first electrode 41A, and the first electrode 41A may have a U shape in cross-section.

Referring to FIG. 5F, a spacer insulating layer 46 may be formed. The spacer insulating layer 46 may be formed to cover the upper surface of the insulating layer 40, the upper surface of the first electrode 41A, the upper surface of the switching pattern 43A, the sidewalls of the oxygen reservoir pattern 44A, and the sidewalls and an upper surface of the second electrode 42A.

Referring to FIG. 5G, the insulating spacer 46A may be formed by etching the spacer insulating layer 46. As an example, the insulating spacer 46A may be formed by performing an etch-back process or a CMP process. The spacer insulating layer 46 may be etched until the upper surface of the second electrode 42A is exposed, and the upper surface of the second electrode 42A and an upper surface of the insulating spacer 46A may be located on substantially the same plane.

According to the manufacturing method described above, the first electrode 41A may be formed to surround the bottom surface and the sidewalls of the switching pattern 43A. The oxygen reservoir pattern 44A and the second electrode 42A may be formed to have a smaller width than the switching pattern 43A. Accordingly, it is possible to form a memory cell in which an electric field is formed in the lateral direction.

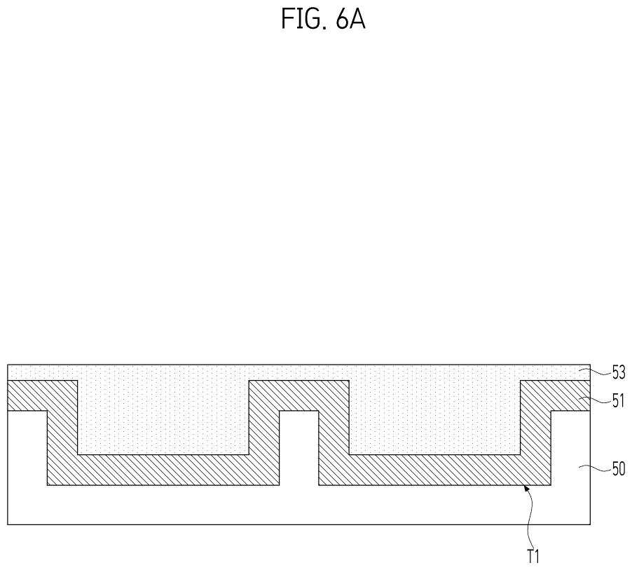

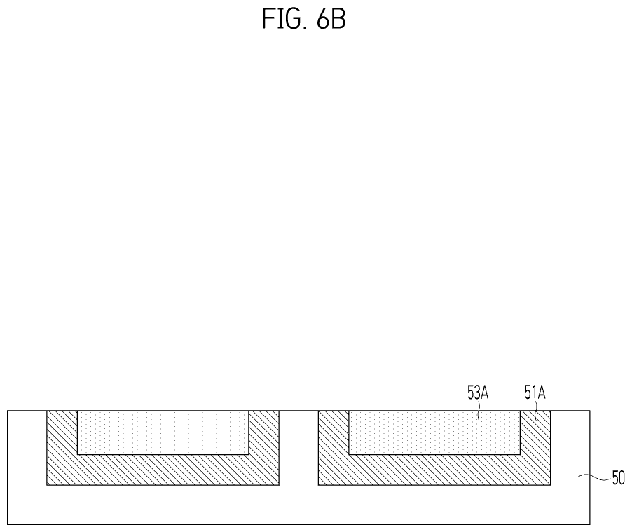

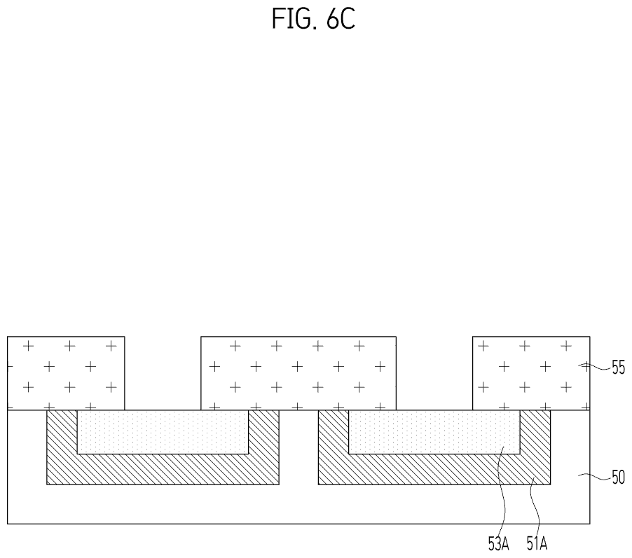

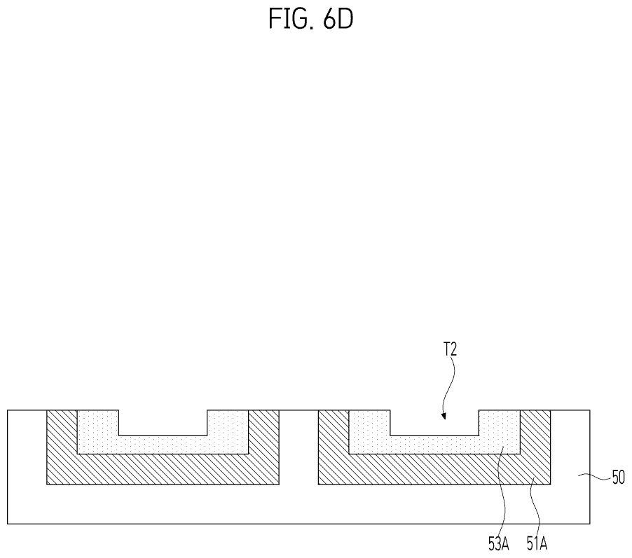

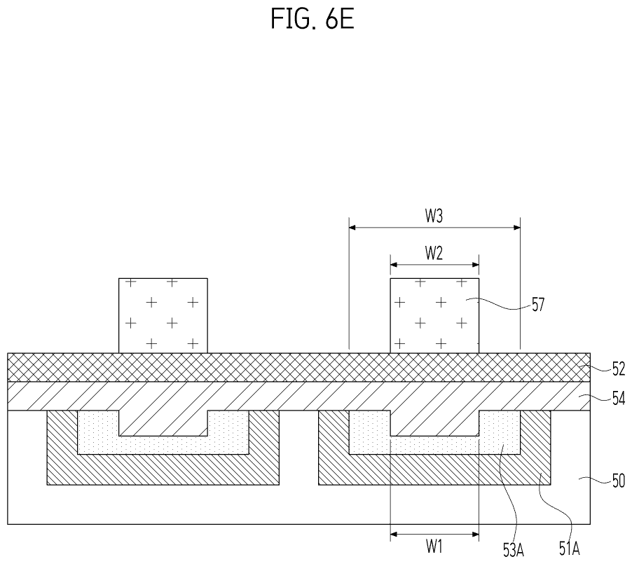

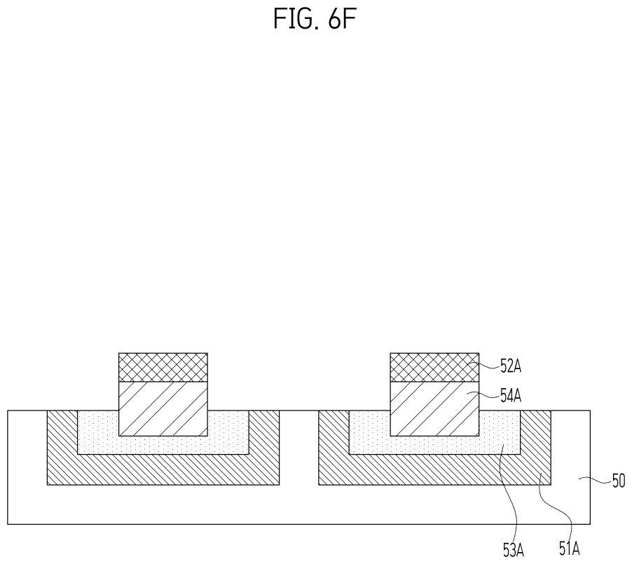

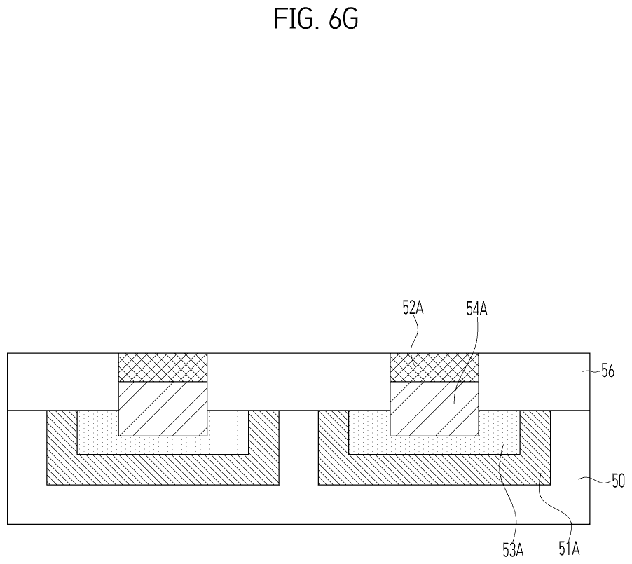

FIGS. 6A to 6G are diagrams for describing a manufacturing method of a semiconductor device in accordance with an embodiment of the disclosure. Hereinafter, content overlapping with the previously described content may be omitted.

Referring to FIGS. 6A to 6G, a first electrode 51A may be formed, a switching pattern 53A may be formed inside the first electrode 51A, an oxygen reservoir pattern 54A having a smaller width than the switching pattern 53A may be formed on the switching pattern 53A, a second electrode 52A may be formed on the oxygen reservoir pattern 54A, and an insulating spacer 56 may be formed on sidewalls of the oxygen reservoir pattern 54A. The order of forming the first electrode 51A, the switching pattern 53A, the oxygen reservoir pattern 54A, the second electrode 52A, and the insulating spacer 56 may be changed depending on a manufacturing method.

Referring to FIG. 6A, first trenches T1 may be formed in an insulating layer 50. Subsequently, a first electrode layer 51 may be formed. The first electrode layer 51 may be formed along a profile of the first trenches T1. Subsequently, a switching layer 53 may be formed on the first electrode layer 51. The switching layer 53 may be formed to fill inner portions of the first trenches T1.

Referring to FIG. 6B, the switching layer 53 and the first electrode layer 51 may be etched. As an example, the switching layer 53 and the first electrode layer 51 may be etched using an etch-back process or a CMP process to form the switching pattern 53A and the first electrode 51A. The first electrode 51A may surround a bottom surface and sidewalls of the switching pattern 53A, and may have a U shape in cross-section. The switching pattern 53A may be located inside the first electrode 51A. Upper surfaces of the switching pattern 53A, the first electrode 51A, and the insulating layer 50 may be located on substantially the same plane.

Referring to FIGS. 6C and 6D, second trenches T2 may be formed in the switching patterns 53A. At least one second trench T2 may be formed in one switching pattern 53A. Each of the second trenches T2 may be formed to a depth at which it does not penetrate through the switching pattern 53A.

Referring to FIG. 6C, a mask pattern 55 partially exposing the switching patterns 53A may be formed. The mask pattern 55 may be a photoresist pattern. As an example, the mask pattern 55 may cover upper surfaces of the insulating layer 50 and the first electrodes 51A. In addition, the mask pattern 55 may cover an edge region of each switching pattern 53A adjacent to the first electrode 51A, and may expose a center region of each switching pattern 53A. Subsequently, referring to FIG. 6D, the second trenches T2 may be formed by etching the switching patterns 53A using the mask pattern 55 as an etching barrier.

Referring to FIG. 6E, an oxygen reservoir layer 54 may be formed on the switching patterns 53A. The oxygen reservoir layer 54 may be formed to fill the second trenches T2, and may be formed on the upper surface of the switching pattern 53A, the upper surface of the first electrode 51A, and the upper surface of the insulating layer 50. Subsequently, a second electrode layer 52 may be formed on the oxygen reservoir layer 54.

A mask pattern 57 may be formed on the second electrode layer 52. The mask pattern 57 may be a photoresist pattern. The mask pattern 57 may be formed to cover the second trench T2. A width W2 of the mask pattern 57 may be substantially the same as or greater than a width W1 of the second trench T2. The width W2 of the mask pattern 57 may be smaller than a width W3 of the switching pattern 53A.

Referring to FIG. 6F, the second electrode layer 52 and the oxygen reservoir layer 54 may be etched using the mask pattern 57 as an etching barrier to form the oxygen reservoir pattern 54A and the second electrode 52A. The oxygen reservoir pattern 54A may fill the second trench T2, and may protrude from the upper surface of the switching pattern 53A. The switching pattern 53A may surround a bottom surface and lower sidewalls of the oxygen reservoir pattern 54A, and may have a U shape in cross-section. Sidewalls of the oxygen reservoir pattern 54A and sidewalls of the second electrode 52A may be aligned with each other.

Referring to FIG. 6G, the insulating spacer 56 may be formed. As an example, a spacer insulating layer may be formed, and then the insulating spacer 56 may be formed by etching the spacer insulating layer until the second electrode 52A is exposed. The insulating spacer 56 may surround upper sidewalls of the oxygen reservoir pattern 54A and the sidewalls of the second electrode 52A. The insulating spacer 56 may extend to the upper surfaces of the switching pattern 53A, the first electrode 51A, and the insulating layer 50.

According to the manufacturing method described above, the first electrode 51A may be formed to surround the bottom surface and the sidewalls of the switching pattern 53A. The switching pattern 53A may be formed to surround the bottom surface and the sidewalls of the oxygen reservoir pattern 54A. A horizontal electric field of a memory cell may be increased by protruding the oxygen reservoir pattern 54A into the switching pattern 53A.

Although embodiments according to the technical idea of the present disclosure have been described above with reference to the accompanying drawings, this is only for explaining the embodiments according to the concepts of the present disclosure, and the present disclosure is not limited to the above embodiments. Various types of substitutions, modifications, changes, and combinations for the embodiments may be made by those skilled in the art, to which the present disclosure pertains, without departing from the technical idea of the present disclosure defined in the following claims, and it should be construed that these substitutions, modifications, changes, and combinations belong to the scope of the present disclosure.

What is claimed is:

1. A semiconductor device comprising:
a first electrode with a trench;
a switching pattern disposed in the trench of the first electrode;
an oxygen reservoir pattern disposed on the switching pattern and having a smaller width in a horizontal direction than the switching pattern;
a second electrode disposed on the oxygen reservoir pattern; and
an insulating spacer surrounding a sidewall of the oxygen reservoir pattern.

2. The semiconductor device of claim 1, wherein the oxygen reservoir pattern protrudes into the switching pattern in a vertical direction.

3. The semiconductor device of claim 2, wherein the switching pattern surrounds a bottom surface of the oxygen reservoir pattern, and extends along the sidewall of the oxygen reservoir pattern.

4. The semiconductor device of claim 1, wherein the oxygen reservoir pattern is disposed in the trench of the first electrode.

5. The semiconductor device of claim 1, wherein the first electrode has a U-shaped cross-section.

6. The semiconductor device of claim 1, wherein the second electrode has a smaller width in the horizontal direction than the switching pattern.

7. The semiconductor device of claim 1, wherein a sidewall of the second electrode and the sidewall of the oxygen reservoir pattern are aligned with each other in a vertical direction.

8. The semiconductor device of claim 1, wherein the insulating spacer surrounds a sidewall of the second electrode.

9. The semiconductor device of claim 1, wherein the insulating spacer extends to an upper surface of the first electrode.

10. The semiconductor device of claim 1, wherein an upper surface of the second electrode and an upper surface of the insulating spacer are on substantially the same plane.

11. The semiconductor device of claim 1, wherein an upper surface of the switching pattern and an upper surface of the first electrode are on substantially the same plane.

12. A semiconductor device comprising:
a switching pattern;
a first electrode surrounding a bottom surface and a sidewall of the switching pattern;
an oxygen reservoir pattern located on the switching pattern;
a second electrode located on the oxygen reservoir pattern and having a smaller width than the switching pattern; and
an insulating spacer located between the first electrode and the second electrode.

13. The semiconductor device of claim 12, wherein the first electrode has a U-shaped cross-section.

14. The semiconductor device of claim 12, wherein an upper surface of the switching pattern is located at a lower level than an upper surface of the first electrode.

15. The semiconductor device of claim 12, wherein an upper surface of the oxygen reservoir pattern is located on the same plane as an upper surface of the first electrode.

16. The semiconductor device of claim 12, wherein the switching pattern and the oxygen reservoir pattern are inside a U-shaped cross-section of the first electrode.

17. The semiconductor device of claim 12, wherein an upper surface of the switching pattern and an upper surface of the first electrode are located on the same plane.

18. The semiconductor device of claim 12, wherein the switching pattern has a U-shaped cross-section.

19. The semiconductor device of claim 12, wherein the switching pattern surrounds a bottom surface and a sidewall of the oxygen reservoir pattern.
